(19) United States
(12) Patent Application Publication
(10) Pub. No.: US 2015/0194321 A1
(43) Pub. Date: Jul. 9, 2015

(54) Methods of Processing Polysilicon-Comprising Compositions

(71) Applicant: Micron Technology, Inc., Boise, ID (US)

(72) Inventors: Guangjun Yang, Meridian, ID (US); Mark Kiehlbauch, Boise, ID (US)

(73) Assignee: Micron Technology, Inc., Boise, ID (US)

(21) Appl. No.: 14/151,499

(22) Filed: Jan. 9, 2014

(51) Int. Cl. H01L 21/3205; H01L 21/3213; H01L 21/768

(52) U.S. Cl. CPC H01L 21/32055; H01L 21/768; H01L 21/32133; H01L 21/76897

(57) ABSTRACT

A method of processing a polysilicon-comprising composition comprises forming a first wall comprising at least one recess in polysilicon. A second wall comprising polysilicon is formed. Material other than polysilicon is deposited within the at least one recess and over the polysilicon of the second wall. The material is etched selectively relative to polysilicon to expose polysilicon of the second wall and to leave the material within the at least one recess in the first wall. The exposed polysilicon of the second wall is etched selectively relative to the material within the at least one recess in the first wall. Other methods are disclosed.

### TECHNICAL FIELD

Embodiments disclosed herein pertain to methods of processing polysilicon-comprising compositions.

### BACKGROUND

A continuing goal in integrated circuitry fabrication is to make ever smaller and closer packed circuit components. As integrated circuitry density has increased, there is often greater reduction in the horizontal dimension of circuit components as compared to the vertical dimension. In many instances, the vertical dimension has increased. As size decreases and density increases, there is a continuing challenge to provide sufficient conductive contact area between electrically coupled circuit components particularly where that coupling is through contacting surfaces that are substantially horizontal.

Polysilicon is one material commonly used in integrated circuitry components. Polysilicon may be largely undoped or slightly doped with conductivity enhancing impurities whereby polysilicon largely functions as a semiconductive material. Alternately, polysilicon may be heavily doped with conductivity enhancing impurities to make it essentially electrically conductive. Regardless, a seam and/or voids can form in polysilicon during its deposition into spaces between tall and closely horizontally-spaced structures. For example, polysilicon can be deposited in highly conformal manners to fill void space between structures by progressing from immediately adjacent sidewalls of the structures to a central region between the structures until the void space is filled. When the structures are sufficiently close and tall, a seam or voids can form particularly in that central region as the depositing polysilicon progressing from each side joins in the middle. These seams or voids commonly form one or more wall recesses in the polysilicon when that polysilicon is subsequently anisotropically etched to produce a desired structure. Polysilicon that is elsewhere on the substrate may need to be removed at the conclusion of the anisotropic polysilicon etch. This is commonly done using an isotropic polysilicon etch. The isotropic etch tends to widen and enlarge the recesses in the polysilicon walls. This may affect continuity of the polysilicon, such as within a contact plug, and can lead to reduced contact area between the polysilicon and the underlying substrate, thereby potentially adversely effecting operation of the circuitry.

### BRIEF DESCRIPTION OF THE DRAWINGS

FIG. 1 is a diagrammatic top plan view of a substrate in process in accordance with an embodiment of the invention.

FIG. 2 is a sectional view taken through line 2-2 in FIG. 1.

FIG. 3 is a sectional view of an alternate embodiment substrate to that of FIG. 2 that corresponds in position to that of FIG. 2.

FIG. 4 is a view of the FIG. 1 substrate at a processing step subsequent to that shown by FIG. 1.

FIG. 5 is a sectional view taken through line 5-5 in FIG. 4.

FIG. 6 is a sectional view taken through line 6-6 in FIG. 4.

FIG. 7 is a sectional view taken through line 7-7 in FIG. 4.

FIG. 8 is an enlarged sectional view of a portion of the FIG. 7 substrate at a processing step subsequent to that shown by FIG. 7.

FIG. 9 is an enlarged sectional view of a portion of the substrate different from and corresponding in processing sequence to that of FIG. 8.

FIG. 10 is a sectional view of an alternate embodiment substrate to that of FIG. 8 that corresponds in position to that of FIG. 8.

FIG. 11 is a sectional view of another alternate embodiment substrate to that of FIG. 8 that corresponds in position to that of FIG. 8.

FIG. 12 is a view of the FIG. 8 substrate at a processing step subsequent to that shown by FIG. 8.

FIG. 13 is a view of the FIG. 9 substrate corresponding in processing sequence to that of FIG. 12.

FIG. 14 is a view of the FIG. 10 substrate at a processing step subsequent to that shown by FIG. 10.

FIG. 15 is a view of the FIG. 11 substrate at a processing step subsequent to that shown by FIG. 11.

FIG. 16 is a view of the FIG. 13 substrate at a processing step subsequent to that shown by FIG. 13.

FIG. 17 is a view of the FIG. 12 substrate corresponding in processing sequence to that of FIG. 16.

FIG. 18 is a sectional view of an alternate embodiment substrate to that of FIG. 16 that corresponds in position to that of FIG. 16.

### DETAILED DESCRIPTION OF EXAMPLE EMBODIMENTS

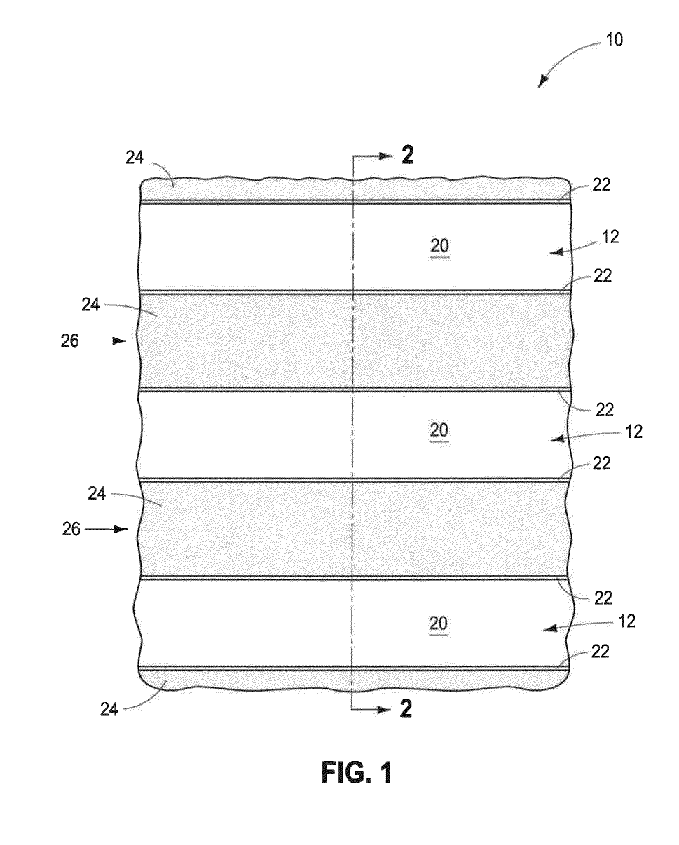

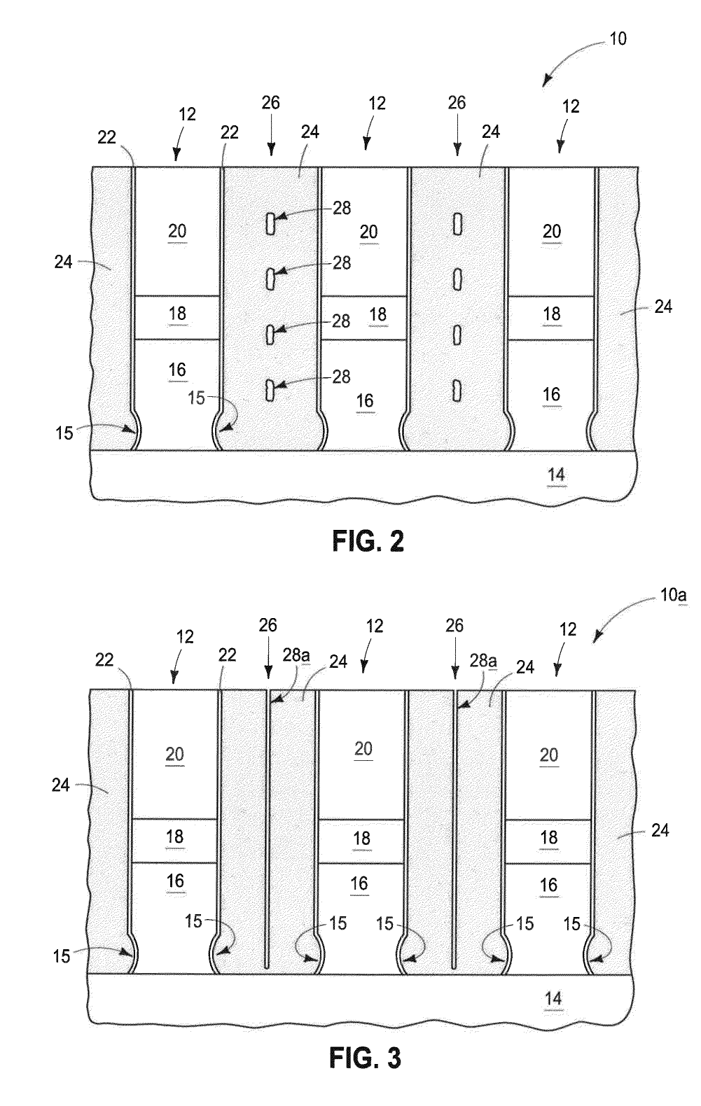

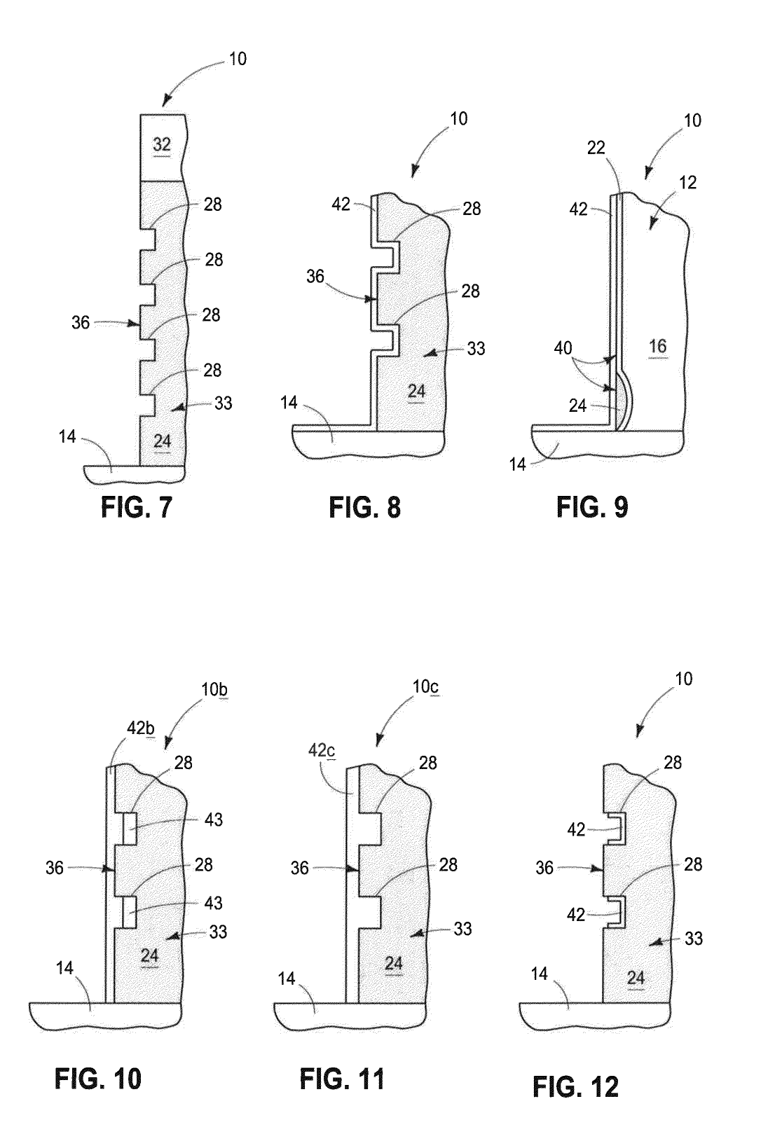

Example methods of processing a polysilicon-comprising composition in accordance with embodiments of the invention are described with reference FIGS. 1-18. Referring to FIGS. 1 and 2, an example substrate fragment 10 includes an underlying substrate 14 over which lines 12 have been formed. Processing associated with the constructions of FIGS. 1-3 is what motivated the invention disclosed herein. However, any alternate constructions may be used which meets that which is in the claims as literally worded.

Substrate 14 may comprise a semiconductor substrate. In the context of this document, the term “semiconductor substrate” or “semiconductive substrate” is defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above. Any of the materials and/or structures described herein may be homogenous or non-homogenous, and regardless may be continuous or discontinuous over any material that such overlie. As used herein, “different composition” only requires those portions of two stated materials that may be directly against one another to be chemically and/or physically different, for example if such materials are not homogenous. If the two stated materials are not directly against one another, “different composition” only requires that those portions of the two stated materials that are closest to one another be chemically and/or physically different if such materials are not homogenous. In this document, a material or structure is “directly against” another when there is at least some physical touching contact of the stated materials or structures relative one another. In contrast, “over”, “on”, and “against” not preceded by “directly”, encompass “directly against” as well as construction where intervening material(s) or structure(s) result(s) in no physical touching contact of the stated materials or structures relative one another. Further, unless otherwise stated, each material may be formed using any suitable or yet-to-be-developed technique, with atomic layer deposition, chemical vapor deposition, physical vapor deposition, epitaxial growth, diffusion doping, and ion implanting being examples.

Example lines 12 comprise materials 16, 18, and 20. As examples, materials 16 and 18 may be electrically conductive, such as material 16 being conductively-doped polysilicon and material 18 being one or more elemental metal(s), an alloy of elemental metals, and/or conductive metal compounds. Material 20 may be dielectric. Lines 12 include laterally-outermost dielectric liners 22. Material 20 and liners 22 may be of the same or different composition, with silicon nitride and silicon dioxide being examples. An example technique of forming lines 12 is to blanket deposit materials 16, 18, and 20, followed by masking and substantially anisotropic etching selectively relative to the masking material. Dielectric liners 22 are then formed. It can be difficult to produce a desired vertical wall profile during anisotropic etching of materials 16, 18, and 20. Additionally, sidewall recessing may occur at one or more elevational locations. For example, opposing recesses 15 are shown as having been formed in material 16.

Polysilicon-comprising material 24 has been formed between lines 12. Polysilicon 24 may be conductively-doped, for example to ultimately form electrically conductive plugs or pillars interconnecting different elevation components of integrated circuitry. A seam and/or voids may form elevationally along a central portion 26 of polysilicon 24 between immediately adjacent lines 12. FIG. 2 shows example voids 28 formed along central portion 26. Voids 28 are shown as being of equal size and spacing relative one another for simplicity in the drawings, although such may be of varying size, shape, and position relative one another. FIG. 3 shows an alternate embodiment to that of FIG. 2 wherein a singular elevationally elongated seam 28a has formed along central portion 26 of a substrate fragment 10a. Like numerals from the FIGS. 1 and 2 embodiment have been used where appropriate, with some construction differences being indicated with the suffix “a”. Seam 28a is shown as extending along most all of the elevational thickness of polysilicon 24 and being open at its top. Such may be of alternate configuration, for example being closed at its top or being an interface of longitudinally contacting polysilicon 24 that occurs from its deposition into the space between the lines largely at the conclusion of the deposition.

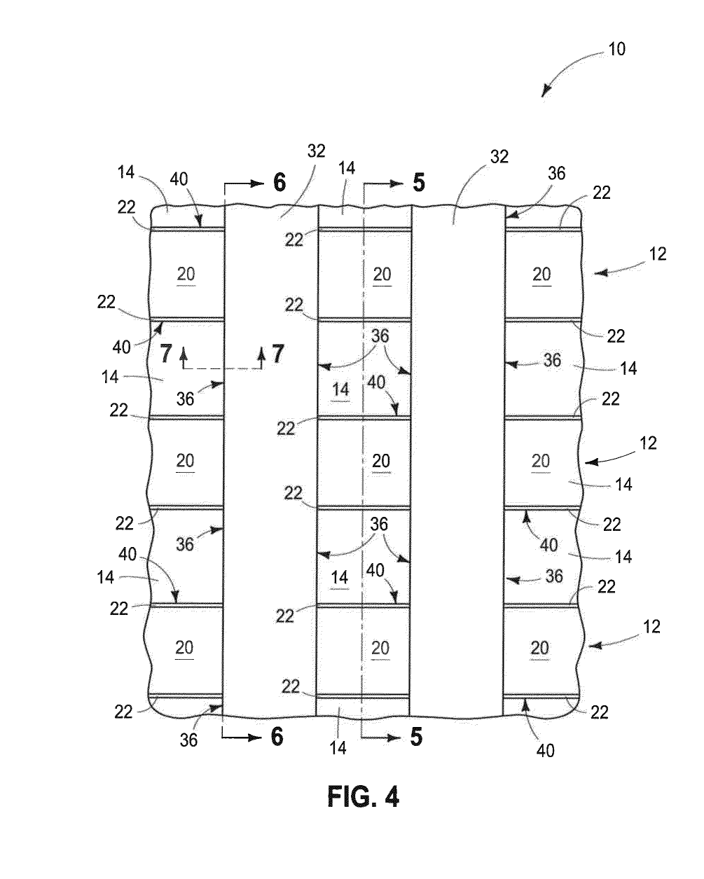

Referring to FIGS. 4-7, mask lines 32 have been formed atop polysilicon 24, and polysilicon 24 has been anisotropically etched selectively relative to materials 20, 14, and materials of liners 22 and mask lines 32. Polysilicon-comprising plugs 33 are thereby formed, and have opposing walls 36 of polysilicon 24. This will open up voids 28 at walls 36, thereby forming recesses 28 in polysilicon 24. Sealed voids (not shown) will most likely remain beneath mask lines 32 laterally away from walls 36. Where a construction like that of FIG. 3 or one with an interface is used in producing the construction of FIG. 4, the recess (not shown) which forms in walls 36 may be in the form of only a single and elevationally elongated recess in polysilicon 24 that may extend partially or wholly laterally there-through. The discussion proceeds with reference to a single wall 36, hereafter referred to as a first wall, although the described processing may inherently occur with respect to multiple first walls 36. Regardless, the first wall may comprise at least one recess in polysilicon, with multiple such recesses 28 being shown with respect to a first wall 36. Recesses 28 may have a minimum lateral depth of about 20 Angstroms. In one embodiment, first wall 36 is substantially vertically oriented. In this document, vertical is a direction generally orthogonal to horizontal, with horizontal referring to a general direction along a primary surface relative to which a substrate is processed during fabrication. Further, “vertical” and “horizontal” as used herein are generally perpendicular directions relative one another independent of orientation of the substrate in three-dimensional space. Additionally, “elevational”, “elevationally”, “above”, and “below” are with reference to the vertical direction

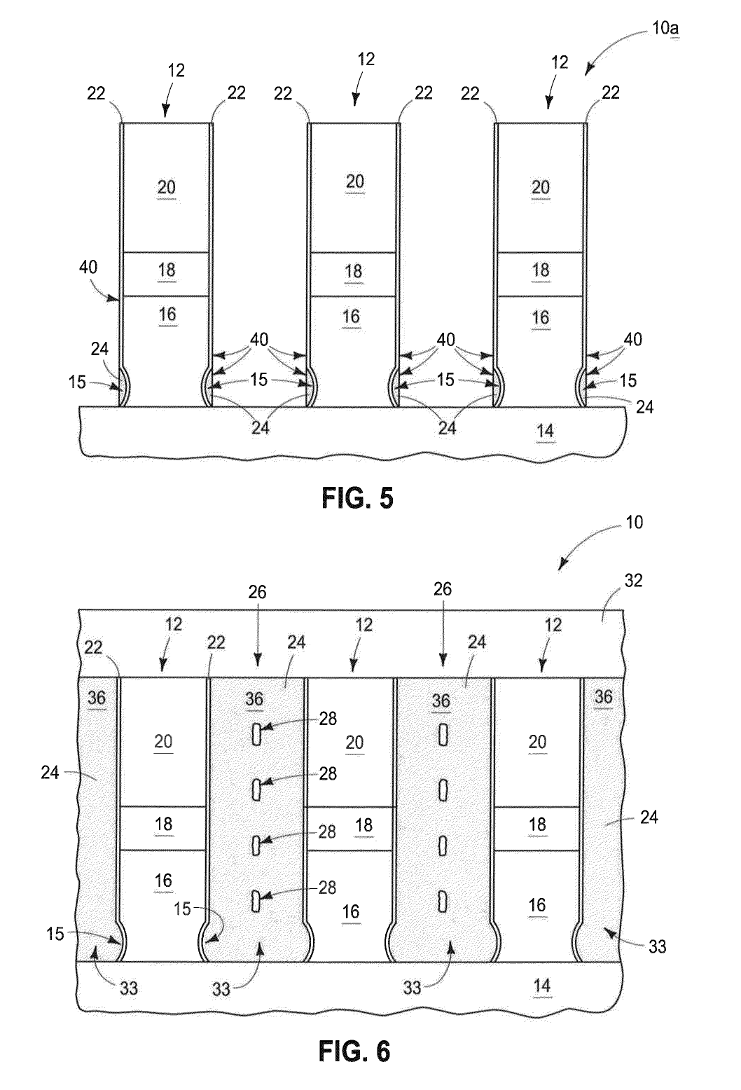

Lines 12 may be considered as comprising walls 40, and in one embodiment and as shown, which may be oriented substantially vertically. The discussion proceeds with reference to a single wall 40, hereafter referred to as a second wall, although the described processing may inherently occur with respect to multiple second walls 40. In one embodiment, first wall 36 and second wall 40 are angled (i.e., other than the straight angle) relative one another, and in one embodiment are angled orthogonally relative one another, for example as is shown. Regardless, second wall 40 comprises polysilicon. Such may result where deposited polysilicon 24 fills line recesses 15 and which is not removed when anisotropically etching polysilicon 24 to form plugs 33, for example as shown in FIGS. 5 and 6. It may be desirable to remove all or at least some of this second wall polysilicon 24 to avoid electrical shorting of immediately adjacent polysilicon plugs 33. In one embodiment, second wall 40 comprises material other than polysilicon (e.g., material of liners 22 in the depicted embodiment).

Referring to FIGS. 8 and 9, different enlarged portions of substrate 10 are shown at a same processing step subsequent to that shown by FIGS. 4-7. Material 42 has been deposited within recesses 28 and over polysilicon 24 of second wall 40. In one embodiment, material 42 is something other than polysilicon (i.e., of different composition than polysilicon). Example materials include at least one of silicon dioxide and silicon nitride. In one embodiment and as shown, material 42 is deposited to line, but not occlude, recesses 28. Alternately, the material may be deposited to occlude the recesses, for example as shown with respect to a substrate fragment 10b in FIG. 10 and a substrate fragment 10c in FIG. 11. Like numerals from the above-described embodiments have been used where appropriate, with some construction differences being indicated with the suffix “b” and “c”, respectively. Material 42b in FIG. 10 has been deposited to occlude but less than completely fill recesses 28, for example thereby forming void spaces 43 within recesses 28. Material 42c in FIG. 11 has been deposited to occlude and completely fill recesses 28.

For forming material 42 to be silicon nitride, example parameters for low pressure chemical vapor deposition (LPCVD) are 50 sccm dichlorosilane (DCS), 150 sccm NH₃, 200 mTorr, 700° C., and deposition time sufficient to deposit from about 10 Angstroms to about 50 Angstroms. For forming material 42 to be silicon dioxide, example parameters for LPCVD are 400 sccm tetraethylorthosilicate, 1,500 sccm N₂, 600 mTorr, 620° C., and deposition time sufficient to deposit from about 10 Angstroms to about 50 Angstroms.

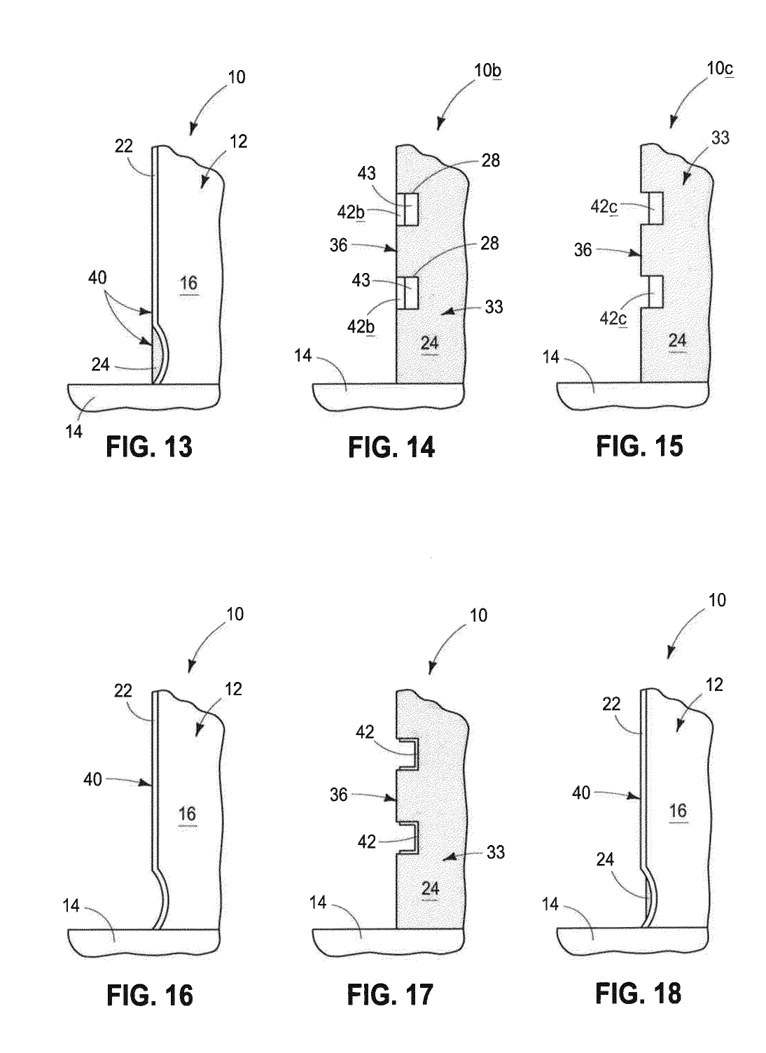

Referring to FIGS. 12 and 13, material 42 has been selectively etched relative to polysilicon to expose polysilicon 24 of second wall 40 and to leave material 42 (i.e., at least some of material 42) within recesses 28 in first wall 36. In this document, a selective etch requires removal of one material relative to another stated material at a rate of at least 2:1. Some, little, or none of material 42 that is within first wall recesses 28 may be removed during the selective etching due to size and geometry of recess 28 and material 42 that is within the recesses versus material 42 that is over second wall polysilicon. FIGS. 14 and 15 show example such etching having occurred relative to alternate embodiment substrates 10b and 10c of FIGS. 10 and 11, respectively. In some embodiments, some of material 42/42b/42c may remain (not shown) over first wall 36 outside of recesses 28.

Example etching of a silicon nitride material 42 selectively relative to polysilicon includes plasma etching in a transformer coupled plasma (TCP) reactor using 35 sccm NF₃, 200 sccm N₂, 10 mTorr, 50° C., 500 W, and low or no bias power, which may achieve a silicon nitride etch rate of about 3 Angstroms per second. Another example is wet etching using 85 wt % H₃PO₄ at 160° C., which may achieve a silicon nitride etch rate of about 30 Angstroms per minute. Example etching of a silicon dioxide material 42 selectively relative to polysilicon includes wet etching with dilute HF (1000:1 water:HF by wt.) or 500:1 BOE (buffered oxide etchant with 500 wt. parts water) at a temperature of 25° C., which may achieve a silicon dioxide etch rate of about 1 Angstrom per second.

Referring to FIGS. 16 and 17, and in one embodiment, exposed polysilicon 24 (not shown) of second wall 40 has been etched selectively relative to material 42 within recesses 28 in first wall 36. FIG. 16 shows one ideal embodiment wherein etching of exposed second wall polysilicon 24 (not shown) removes all of polysilicon 24 of second wall 40. FIG. 18 shows a less-than-ideal embodiment wherein etching of exposed polysilicon 24 removes less-than-all of polysilicon 24 of second wall 40. In an embodiment where the exposed second wall polysilicon is etched selectively relative to different composition material that is within the first wall recess, some, none, or even all of that material within the first wall recess may be removed. FIG. 17 depicts the substrate of FIG. 12 corresponding in processing sequence to that of FIG. 16, and wherein some of material 42 has been removed from within first wall recesses 28 in comparison to FIG. 12. Example etching of polysilicon selectively relative to silicon nitride and silicon dioxide includes plasma etching in a TCP chamber using 10 sccm SF₆, 150 sccm Ar, 5 mTorr, 50° C., 350 W, and low or no bias power, which may achieve a polysilicon etch rate of about 4 Angstroms per second.

In one embodiment, both material 42 that is over polysilicon 24 of second wall 40 and material 42 that is within first wall recesses 28 (e.g., as shown in FIGS. 8 and 9) are etched, and in one embodiment such etching is conducted non-selectively relative to polysilicon. Regardless, in such embodiments, second wall polysilicon upon its exposure is etched. Greater thickness of second wall polysilicon is etched than any thickness, if any, of polysilicon that is etched from polysilicon walls of the recesses. Less etching of polysilicon 24 from walls of recesses 28 may occur due to size and geometry of recesses 28 and material 42 that is within recesses 28 versus material 42 that is over second wall polysilicon 24. For example, material 42 within depicted recesses 28 may be laterally thicker than lateral thickness of material 42 over second wall 40. This may result in material 42 in recesses 28 not being completely etched away from being over polysilicon 24 within recesses 28. Alternately even if it is completely removed, it may protect the polysilicon walls of recesses 28 longer than material 42 protects second wall polysilicon 24, resulting in less removal, if any, of polysilicon from within recesses 28. Accordingly, during etching of the second wall polysilicon, some or no measurable etching of polysilicon may occur from the polysilicon walls within the first wall recesses. In one embodiment, the etching of the material other than polysilicon and the etching of the polysilicon may be conducted continuously using a single etching chemistry, and in one such embodiment with the etching parameters being kept constant during the continuous single-chemistry etching.

An example technique for etching polysilicon, silicon nitride, and silicon dioxide non-selectively relative one another includes plasma etching in a TCP etch chamber (e.g., with a Lam 2300 Kiyo™ reactor available from LamResearch), 150 sccm CF₄, 180 sccm N₂, 10 mTorr, 50° C., 550 W, and no or low bias power, which may achieve an etch rate of about 2 Angstroms per second. As another example, polysilicon and silicon nitride can be non-selectively etched relative one another by wet etching using HF (e.g., 25:1 water:HF by wt.) at 25° C., which may achieve an etch rate of about 2 Angstroms per minute.

In some embodiments of the invention, material 42 can be silicon. In such embodiments, silicon is deposited within the first wall recesses and over the already-existing polysilicon of the second wall. An example technique for depositing polysilicon includes LPCVD using 800 sccm SiH₄, 80 sccm N₂, 500 mTorr, and 580° C. Dopants such as phosphine, arsine, and/or diborane can be added during deposition to enhance polysilicon conductivity. Another example technique for depositing epitaxial silicon includes LPCVD using 100 sccm DCS, 95 sccm HCl, 5,000 sccm H₂, 40 Torr, and 850° C.

Then, the deposited silicon that is over the second wall and that which is within the recesses is etched. Further, the polysilicon of the second wall that is under the deposited silicon is also etched. The etching of the deposited silicon removes all of the deposited silicon that is over the second wall. Again and analogously, size and geometry of the recesses and of the deposited silicon (e.g., material 42) that is within the recesses versus the deposited silicon that is over the previously formed polysilicon (e.g., polysilicon 24) can result in greater thickness removal of second wall polysilicon than removal of thickness of all first wall silicon. Any of the above described example techniques that etch polysilicon may be used.

In one embodiment, the etching of the second wall polysilicon that is under the deposited silicon removes all of the second wall polysilicon that is under the deposited silicon (e.g., FIG. 16). Alternately in a less-ideal example, the etching of the second wall polysilicon that is under the deposited silicon removes less than all of the second wall polysilicon that is under the deposited silicon (e.g., FIG. 18).

In one embodiment, the etching of the deposited silicon removes only some of that which is within the first wall recesses (e.g., some material 42/42b/42c remains with recesses 28 after the etching). In one embodiment, the etching of the deposited silicon removes all (not shown) of the deposited silicon that is within the at least one recess. For example, no material 42/42b/42c may remain within recesses 28 at the conclusion of the etching.

### CONCLUSION

In some embodiments, a method of processing a polysilicon-comprising composition comprises forming a first wall comprising at least one recess in polysilicon. A second wall comprising polysilicon is formed. Material other than polysilicon is deposited within the at least one recess and over the polysilicon of the second wall. The material is etched selectively relative to polysilicon to expose polysilicon of the second wall and to leave the material within the at least one recess in the first wall. The exposed polysilicon of the second wall is etched selectively relative to the material within the at least one recess in the first wall.

In some embodiments, a method of processing a polysilicon-comprising composition comprises forming a first wall comprising at least one recess in polysilicon. A second wall comprising polysilicon is formed. Material other than polysilicon is deposited within the at least one recess and over the polysilicon of the second wall. The material that is over the polysilicon of the second wall and that which is within the at least one recess are etched. The polysilicon of the second wall is etched. Greater thickness of second wall polysilicon is etched than any thickness, if any, of polysilicon that is etched from polysilicon walls of the recesses.

In some embodiments, a method of processing a polysilicon-comprising composition comprises forming a first wall comprising at least one recess in polysilicon. A second wall comprising polysilicon is formed. Silicon is deposited within the at least one recess and over the polysilicon of the second wall. The deposited silicon that is over the second wall and that which is within the at least one recess are etched. The polysilicon of the second wall that is under the deposited silicon is etched. The etching of the deposited silicon removes all of said deposited silicon that is over the second wall.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method of processing a polysilicon-comprising composition, comprising:
forming a first wall comprising at least one recess in polysilicon;
forming a second wall comprising polysilicon;
depositing material other than polysilicon within the at least one recess and over the polysilicon of the second wall;
etching the material selectively relative to polysilicon to expose polysilicon of the second wall and to leave the material within the at least one recess in the first wall; and
etching the exposed polysilicon of the second wall selectively relative to the material within the at least one recess in the first wall.

2. The method of claim 1 wherein the second wall comprises material other than polysilicon.

3. The method of claim 1 wherein the first wall comprises multiple recesses in polysilicon.

4. The method of claim 1 wherein the first wall comprises only a single and elevationally elongated recess in polysilicon.

5. The method of claim 1 wherein the material comprises at least one of silicon dioxide and silicon nitride.

6. The method of claim 1 wherein the material is deposited to Iine but not occlude the at least one recess.

7. The method of claim 1 wherein the material is deposited to occlude the at least one recess.

8. The method of claim 7 wherein the material is deposited to completely fill the at least one recess.

9. The method of claim 7 wherein the material is deposited to less than completely fill the at least one recess.

10. The method of claim 1 wherein the first wall and the second wall are angled relative one another.

11. The method of claim 10 wherein the first wall and the second wall are angled orthogonally relative one another.

12. The method of claim 1 wherein at least of one of the first and second walls is substantially vertically oriented.

13. The method of claim 12 wherein each of the first and second walls is substantially vertically oriented.

14. The method of claim 1 wherein etching the exposed polysilicon removes all of the polysilicon of the second wall.

15. The method of claim 1 wherein etching the exposed polysilicon removes less than all of the polysilicon of the second wall.

16. A method of processing a polysilicon-comprising composition, comprising:
forming a first wall comprising at least one recess in polysilicon;
forming a second wall comprising polysilicon;
depositing material other than polysilicon within the at least one recess and over the polysilicon of the second wall;
etching the material that is over the polysilicon of the second wall and that which is within the at least one recess; and
etching the polysilicon of the second wall, greater thickness of second wall polysilicon being etched than any thickness, if any, of polysilicon that is etched from polysilicon walls of the recesses.

17. The method of claim 16 wherein etching the material is conducted non-selectively relative to polysilicon.

18. The method of claim 16 wherein etching the material and etching the polysilicon is conducted continuously using a single etching chemistry.

19. The method of claim 18 wherein etching parameters are constant during the continuous single-chemistry etching.

20. The method of claim 16 comprising measurably etching polysilicon from within the at least one recess while etching the polysilicon of the second wall.

21. The method of claim 16 wherein no measurable etching of polysilicon from within the at least one recess occurs while etching the polysilicon of the second wall.

22. A method of processing a polysilicon-comprising composition, comprising:
forming a first wall comprising at least one recess in polysilicon;
forming a second wall comprising polysilicon;
depositing silicon within the at least one recess and over the polysilicon of the second wall; and
etching the deposited silicon that is over the second wall and that which is within the at least one recess, and etching the polysilicon of the second wall that is under the deposited silicon, the etching of the deposited silicon removing all of said deposited silicon that is over the second wall.

23. The method of claim 22 wherein the etching of the second wall polysilicon that is under the deposited silicon removes all of the second wall polysilicon that is under the deposited silicon.

24. The method of claim 22 wherein the etching of the second wall polysilicon that is under the deposited silicon removes less than all of the second wall polysilicon that is under the deposited silicon.

25. The method of claim 22 wherein the etching of the deposited silicon removes only some of the deposited silicon that is within the at least one recess.

26. The method of claim 25 wherein the etching of the second wall polysilicon that is under the deposited silicon removes all of the second wall polysilicon that is under the deposited silicon.

27. The method of claim 25 wherein the etching of the second wall polysilicon that is under the deposited silicon removes less than all of the second wall polysilicon that is under the deposited silicon.

28. The method of claim 22 wherein the etching of the deposited silicon removes all of the deposited silicon that is within the at least one recess.

29. The method of claim 28 wherein the etching of the second wall polysilicon that is under the deposited silicon removes all of the second wall polysilicon that is under the deposited silicon.
